(19) United States
(12) Patent Application Publication
(10) Pub. No.: US 2025/0218637 A1
(43) Pub. Date: Jul. 3, 2025

(54) Inductors Including Magnetic Films with Trenches

(71) Applicant: Apple Inc., Cupertino, CA (US)

(72) Inventors: Hamidreza Kazemi varnamkhasti, San Diego, CA (US); Zhang Jin, San Diego, CA (US); Aly Ismail, San Diego, CA (US); David P. Cappabianca, San Jose, CA (US)

(21) Appl. No.: 18/400,682

(22) Filed: Dec. 29, 2023

(51) Int. Cl. H01F 10/08; H01L 23/498

(52) U.S. Cl. CPC H01F 10/08; H01L 23/49811; H10D 1/20

(57) ABSTRACT

An inductor for an integrated circuit may include a conductive trace and one or more magnetic films surrounding a top, a bottom, and sides of the conductive trace. The one or more magnetic films may include one or more trenches along a first path directly above a length of the conductive trace, and one or more trenches along a second path directly above a width of the conductive trace, to form a plurality of sections of the magnetic film. In some implementations, one or more multi-layer stacks may surround a top, a bottom, and sides of the conductive trace. Other aspects are also described and claimed.

### BACKGROUND

### Field

This disclosure relates generally to inductors for integrated circuits and, more specifically, to inductors including conductive traces and magnetic films for radio frequency integrated circuits.

### Background Information

Inductors are passive components that store energy in a magnetic field based on a flow of electric current. An inductor may include a conductive trace having two terminals and may have a shape that forms an open loop or coil. Inductors may be utilized in radio frequency (RF) integrated circuits (ICs), for example, to implement filters, impedance matching networks, resonators, couplers, and other circuitry elements. For example, for example, some ICs utilize inductors in circuitry to implement mobile network technology.

One measure of efficiency of an inductor is a quality factor (or Q factor) of the inductor. A Q factor of an inductor generally refers to a ratio of inductive reactance to resistance at a given frequency. The Q factor may be a measure of efficiency where a higher Q factor is closer in behavior to an ideal inductor.

### SUMMARY

Implementations of this disclosure include surrounding a conductive trace of an inductor with one or more magnetic films having trenches (e.g., dielectric spacers) in multiple directions. The trenches may form sections (e.g., islands or patches) of magnetic film surrounding the conductive trace in three dimensions. Some implementations may include an inductor for an RF IC. The inductor may include a conductive trace and one or more magnetic films, including one or more layers of magnetic film alternating with one more layers of dielectric. The conductive trace may have two terminals and a shape that forms an open loop or coil. The one or more magnetic films may surround a top, a bottom, and sides of the conductive trace. The one or more magnetic films may include one or more trenches along a first path directly above a length of the conductive trace and one or more trenches along a second path directly above a width of the conductive trace to form the sections. The trenches of the one or more magnetic films may pass completely through the one or more magnetic films between the sections. In some implementations, one or more multi-layer stacks comprising the one or more magnetic films may surround a top, a bottom, and sides of the conductive trace. The one or more multi-layer stacks may be formed as laminates in a lamination process. The one or more multi-layer stacks may include layers of magnetic film separated from one another by layers of dielectric. The multi-layer stack may also include one or more trenches along a path directly above a length or a width of the conductive trace to form a plurality of sections of the one or more multi-layer stacks. Other aspects are also described and claimed.

The above summary does not include an exhaustive list of all aspects of the present disclosure. It is contemplated that the disclosure includes all systems and methods that can be practiced from all suitable combinations of the various aspects summarized above, as well as those disclosed in the Detailed Description below and particularly pointed out in the Claims section. Such combinations may have particular advantages not specifically recited in the above summary.

### BRIEF DESCRIPTION OF THE DRAWINGS

Several aspects of the disclosure here are illustrated by way of example and not by way of limitation in the figures of the accompanying drawings in which like references indicate similar elements. It should be noted that references to “an” or “one” aspect in this disclosure are not necessarily to the same aspect, and they mean at least one. Also, in the interest of conciseness and reducing the total number of figures, a given figure may be used to illustrate the features of more than one aspect of the disclosure, and not all elements in the figure may be required for a given aspect.

FIG. 1 is an example of an inductor including a conductive trace and one or more magnetic films with trenches in accordance with an embodiment.

FIG. 2 is an example of a top view of the inductor of FIG. 1.

FIG. 3 is an example of a side view of the inductor of FIG. 1.

FIG. 4 is an example of a close-up, top view of the inductor of FIG. 1.

FIG. 5 is an example of a close-up, side view of the inductor of FIG. 1.

FIGS. 6A-6F are examples of inductors including one or more conductive traces and one or more multi-layer stacks in accordance with embodiments.

FIGS. 7A-7E are examples of top view patterns and side view patterns of conductive traces of inductors including magnetic films with trenches in accordance with embodiments, and FIG. 7F is an example of a top view and a side view of a conductive trace of a reference inductor without magnetic film.

FIG. 8 is an example of an inductor formed in a back-end-of-the-line build-up structure in accordance with an embodiment.

FIG. 9 is an example of an inductor formed in a die level redistribution layer in accordance with an embodiment.

FIG. 10 is an example of thin film fabrication in accordance with an embodiment.

FIG. 11 is an example of dual damascene fabrication in accordance with an embodiment.

FIG. 12 is an example of an inductor formed in a package level redistribution layer in accordance with an embodiment.

FIG. 13 is an example of an inductor comprised of a discrete integrated passive device coupled to a discrete die in accordance with an embodiment.

### DETAILED DESCRIPTION

To improve radio frequency (RF) integrated circuits (ICs), for example, to implement fifth generation (5G) mobile network technology, it is desirable for inductors to occupy smaller areas with higher inductance densities and higher quality factors (or Q factors). However, many inductors for ICs suffer from smaller inductances per unit area and higher losses (quantified by lower Q factors). To overcome these limitations, monolithic integration of IC-compatible metallic ferromagnetic films may be utilized. These films comprise thin layers of magnetic material having a high permeability. Designing the shape, size, and thickness of magnetic films may enhance performance of the inductor, and in turn, performance of the circuit.

Nevertheless, high-energy dissipation brought about by parasitic eddy currents in metallic ferromagnetic layers, and the limited frequency range of operation due to ferromagnetic resonance, may limit the performance of inductors. For example, while the use of thick magnetic films can bring about an increase in inductance, an increase of magnetic film thickness can also reduce the Q factor of the inductor due to enhanced eddy current loss. This may render utilization of thicker magnetic films impractical. It is therefore desirable to improve performance of inductors (e.g., to achieve higher inductance per unit area and a higher Q factor) in ICs while reducing high-energy dissipation due to eddy currents.

Implementations of this disclosure include surrounding a conductive trace of an inductor with one or more magnetic films having trenches (e.g., dielectric spacers) in multiple directions. The trenches may form sections (e.g., islands or patches) of magnetic film surrounding the conductive trace in three dimensions. Some implementations may include an inductor for an RF IC. The inductor may include a conductive trace and one or more magnetic films, including one or more layers of magnetic film alternating with one more layers of dielectric. The conductive trace may have two terminals and a shape that forms an open loop or coil. The one or more magnetic films may surround a top, a bottom, and sides of the conductive trace. The one or more magnetic films may include one or more trenches along a first path directly above a length of the conductive trace and one or more trenches along a second path directly above a width of the conductive trace to form the sections. The trenches of the one or more magnetic films may pass completely through the one or more magnetic films between the sections. In some implementations, one or more multi-layer stacks comprising the one or more magnetic films may surround a top, a bottom, and sides of the conductive trace. The one or more multi-layer stacks may be formed as laminates in a lamination process (e.g., a deposition or plated lamination process). The one or more multi-layer stacks may include layers of magnetic film separated from one another by layers of dielectric. The multi-layer stack may also include one or more trenches along a path directly above a length or a width of the conductive trace to form a plurality of sections of the one or more multi-layer stacks. As a result, the inductor may operate with improved performance (e.g., higher inductance per unit area and a higher Q factor) while reducing high-energy dissipation due to eddy currents.

In some implementations, a three dimensional magnetic film may be patterned to maximize the quality factor of an inductor. The magnetic film can increase the magnetic flux density around the inductor based on its high permeability. The magnetic film may be patterned to mitigate eddy currents and, in turn, mitigate power dissipation in the system, resulting from high conductivity of the magnetic film. For example, losses due to eddy currents can degrade the Q factor of the inductor even though high permeability of the magnetic film increases the Q factor. To reduce the eddy currents, one or more magnetic films may be formed with trenches filled with a dielectric, such as polyimide or air (e.g., dielectric spacers). This can the limit eddy current that circulates in the structure and reduce the overall loss. However, forming magnetic film with trenches can reduce the spatial density of magnetic film around the inductor. This may result in a smaller magnetic flux density and lower Q factor. Therefore, in embodiments described herein, the formed pattern of magnetic films may be optimized to achieve an optimum balance between inductance density per unit length and total loss due to eddy current to achieve a highest Q factor.

In some implementations, an optimized pattern may include forming a magnetic film with one or more trenches in an X direction (e.g., across a width of a conductive trace), a Y direction (e.g., across a length of the conductive trace), and/or a Z direction (e.g., across a thickness of the conductive trace). For example, the magnetic film may be formed uniformly by the trenches to include many sections in both Y and Z directions. The optimized pattern of magnetic film may also include more than two trenches in an X direction. The spacing between layers of magnetic film, and between the trenches in the X direction, may be optimized to have a highest Q factor.

Several aspects of the disclosure with reference to the appended drawings are now explained. Whenever the shapes, relative positions and other aspects of the parts described are not explicitly defined, the scope of the invention is not limited only to the parts shown, which are meant merely for the purpose of illustration. Also, while numerous details are set forth, it is understood that some aspects of the disclosure may be practiced without these details. In other instances, well-known circuits, structures, and techniques have not been shown in detail so as not to obscure the understanding of this description. The terms “above”, “below,” “over”, “under,” “top,” “bottom,” “side,” “to,” “between,” “spanning,” and “on” as used herein may refer to a relative position of one layer with respect to other layers. One layer terms “above”, “below,” “over”, “under,” “top,” “bottom,” to a “side,” “between,” “spanning,” or “on” another layer or bonded “to” or in “contact” with another layer may be directly in contact with the other layer or may have one or more intervening layers (e.g., dielectric layers). One layer “between” layers may be directly in contact with the layers or may have one or more intervening layers (e.g., dielectric layers).

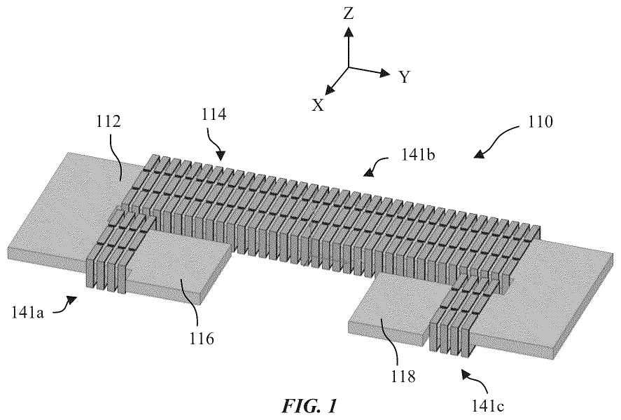

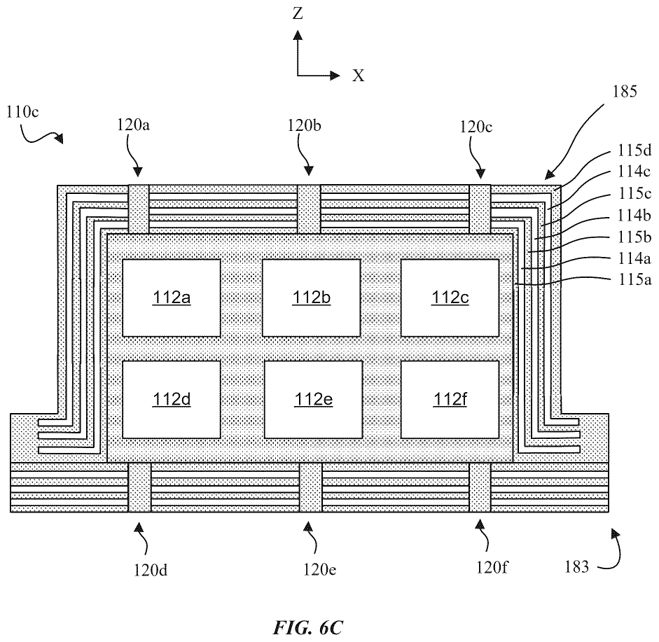

FIGS. 1-5 will now be described to explain possible embodiments, including as shown in FIGS. 6A-6D. FIG. 1 is an example of an inductor 110 including a conductive trace 112 and one or more layers of magnetic film 114 with trenches in accordance with an embodiment. The one or more layers of magnetic film 114 with trenches could be implemented by the multi-layer stacks shown in any of FIGS. 6A-6D. The conductive trace 112 (e.g., copper) may include two terminals 116 and 118 for connecting to circuitry of an IC or IC package. The conductive trace 112 may be formed in an open loop. The inductor 110 may be utilized, for example, in a filter, impedance matching network, resonator, coupler, or other circuitry element. For example, the inductor 110 may be utilized in circuitry of an IC that implements 5G mobile network technology. Each layer of magnetic film may comprise an IC-compatible metallic ferromagnetic material having a high permeability. The one or more layers of magnetic film 114 may be monolithically integrated with the IC. The one or more layers of magnetic film 114 may comprise a plurality of magnetic films surrounding the conductive trace 112. For example, the plurality of magnetic films may be a multi-layer stack including layers of magnetic film separated by layers of dielectric, including as shown in FIGS. 6A-6D.

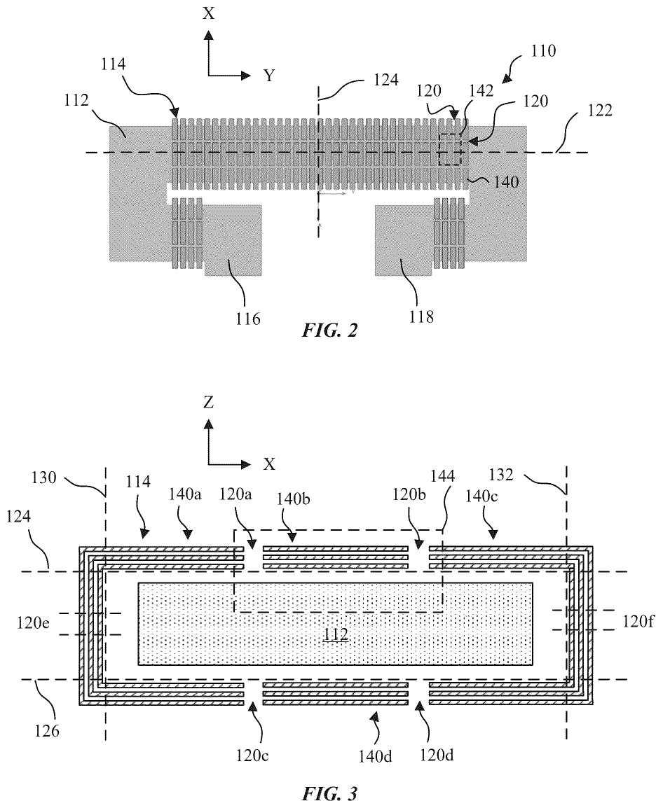

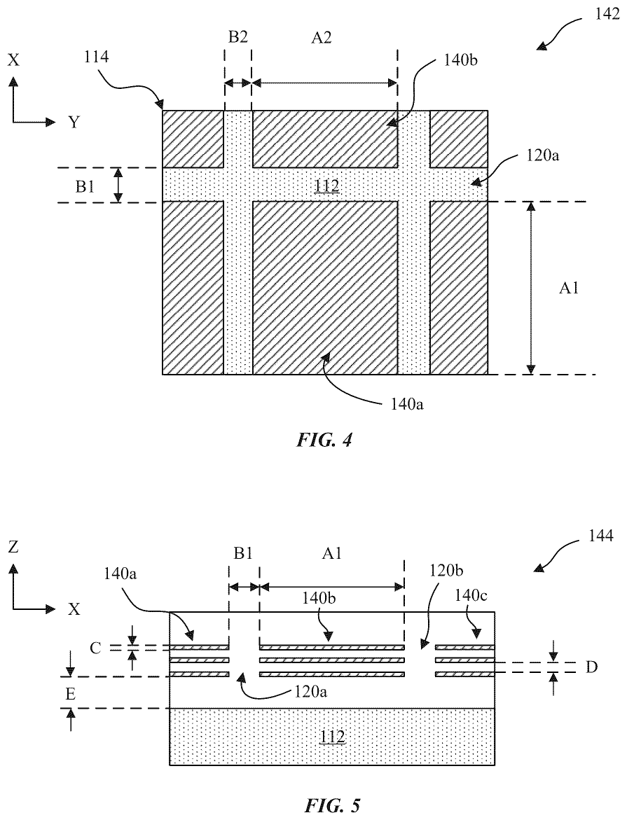

With additional reference to FIGS. 2 and 3, a top view of the inductor 110 and a side view of the inductor 110, respectively, are shown by way of example. The one or more layers of magnetic film 114 may be patterned to surround a top, bottom, and sides (e.g., opposing sides, such as a first side and a second side) of the conductive trace 112. The one or more layers of magnetic film 114 may include one or more trenches 120 arranged along a first path 122 directly above a length of the conductive trace 112. For example, the first path 122 could be in a Y direction above the conductive trace 112 and along a length of the conductive trace 112 (e.g., more than thirty trenches shown in FIG. 2). The one or more layers of magnetic film 114 may also include one or more trenches 120 arranged along a second path 124 directly above a width of the conductive trace 112. For example, the second path 124 could be in an X direction above the conductive trace 112 and across the width of the conductive trace 112 (e.g., three trenches shown in FIG. 2). The one or more layers of magnetic film 114 may also include one or more trenches 120 arranged along a third path 126 directly below the width of the conductive trace 112. For example, the third path 126 could be in the X direction below the conductive trace 112 and across the width of the conductive trace 112 (e.g., three trenches in another path parallel to the second path 124). The one or more layers of magnetic film 114 may also include one or more trenches 120 arranged along a fourth path directly below the length of the conductive trace 112. For example, the fourth path could be in the Y direction below the conductive trace 112 and along a length of the conductive trace 112 (e.g., more than thirty trenches in another path parallel to the first path 122).

In some implementations, the one or more layers of magnetic film 114 may also include one or more trenches 120e (indicated in phantom lines in FIG. 3) arranged along a fifth path 130 directly across a thickness of the conductive trace 112 on a first side, and/or one or more trenches 120f (indicated in phantom lines in FIG. 3) arranged along a sixth path 132 directly across a thickness of the conductive trace 112 on a second side (see FIG. 3). For example, the trenches 120 may be arranged vertically and horizontally relative to the conductive trace 112. The fifth path 130 and the sixth path 132 could each be in a Z direction on opposing sides of the conductive trace 112 and across a thickness of the conductive trace 112 (e.g., in paths parallel to one another).

The trenches 120 may form a plurality of sections (e.g., islands or patches) of magnetic film, such as sections 140. Further, the trenches 120 may pass completely through the one or more layers of magnetic film 114, including through multiple layers and between the sections 140, and may be filled with dielectric such as polyimide or air (e.g., forming dielectric spacers between the sections 140). For example, as shown in the side view of FIG. 3, trenches 120a, 120b, 120c, and 120d may pass completely through multiple layers of the one or more layers of magnetic film 114, with dielectric in between, to form sections 140a, 140b, 140c, and 140d (e.g., multi-layer sections that are electrically separate from one another). As a result, the inductor 110 may operate with improved performance, such as higher inductance per unit area and a higher Q factor, while reducing high-energy dissipation due to eddy currents.

In some implementations, one or more trenches 120 along one path may be aligned with the one or more trenches 120 along another path. For example, as shown in the side view of FIG. 3, trenches 120a and 120b along the second path 124 are axially aligned (e.g., in the Z direction) with trenches 120c and 120d along the third path 126. In another example, trenches 120 along the first path 122 may be aligned (e.g., in the Z direction) with trenches 120 along the fourth path directly below the length of the conductive trace 112. In yet another example, trenches 120 along the fifth path 130 may be aligned (e.g., in the X direction) with trenches 120 along the sixth path 132. Thus, patterning of the trenches 120 above the conductive trace 12 may be the same as the patterning of the trenches 120 below the conductive trace 12. Further, patterning of the trenches 120 on opposing sides of the conductive trace 12 may be the same.

In some implementations, one or more trenches 120 along one path may be offset relative to one or more trenches 120 along another path (e.g., a parallel path in another plane). For example, in some implementations, trenches 120a and 120b along the second path 124 could be axially offset (e.g., in the Z direction) relative to trenches 120c and 120d along the third path 126. Thus, patterning of the trenches 120 above the conductive trace 12 may be different than patterning of the trenches 120 below the conductive trace 12. Further, patterning of the trenches 120 may be different on opposing sides of the conductive trace 12.

Thus, one or more layers of magnetic film 114 may be patterned, via the trenches 120, to optimize the inductor 110, such as to increase or maximize the Q factor. Each layer of magnetic film can increase the magnetic flux density around the inductor 110 based on its high permeability. The one or more layers of magnetic film 114 may be patterned, via the trenches 120, to mitigate eddy currents and, in turn, mitigate power dissipation in the system, resulting from high conductivity of the magnetic film. The patterning of the one or more layers of magnetic film 114, such as by laser etching, dry reactive etching, or plasma etching, may be optimized to achieve an optimum balance between inductance density per unit length and total loss due to eddy current to achieve a highest Q factor.

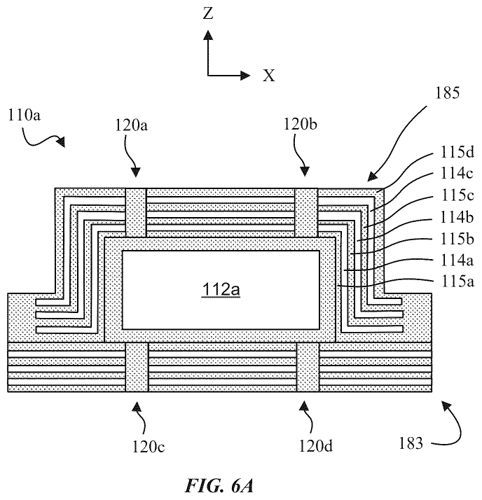

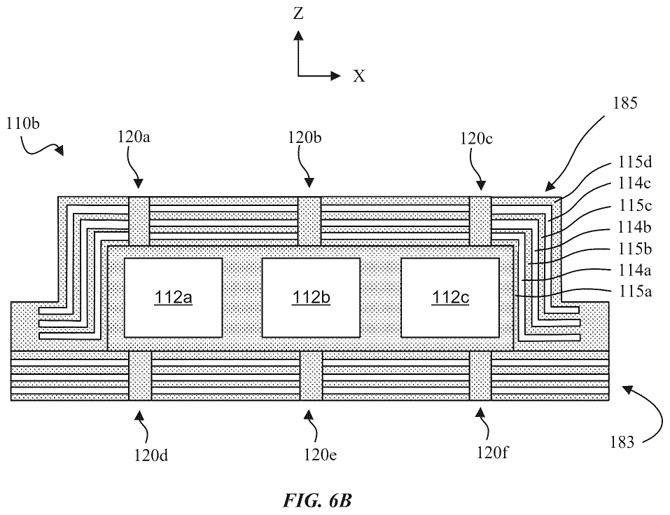

With additional reference to FIGS. 4 and 5, a close-up, top view 142 of the inductor 110 and a close-up, side view 144 of the inductor 110, respectively, are shown by way of example. Sections 140 (e.g., sections 140a, 140b, and 140c) of the one or more layers of magnetic film 114 may have a width A1, a length A2, and a thickness C. For example, for a 142 picohenry (pH) inductor optimized at 7 GHZ, sections 140 could have a width A1 of 1.9 micrometers (μm), a length A2 of 1.9 μm, and a thickness C of 1125 nanometers (nm). Sections 140 may also be spaced from one another in the X direction by a distance B1 and in the Y direction by a distance B2. The distances B1 and B2 may correspond to dimensions of the trenches 120. For example, for the 142 pH inductor, sections 140 could be spaced from one another in the X direction by a distance B1 of 0.95 μm and in the Y direction by a distance B2 of 0.95 μm. Sections 140 may also be spaced from one another in the Z direction by a distance D (e.g., a distance between layers of magnetic film). For example, for the 142 pH inductor, sections 140 could be spaced from one another in the Z direction by a distance D of 50 nm. Sections 140 may also be spaced from the conductive trace 112 by at least a distance E. For example, for the 142 pH inductor, sections 140 could be spaced from the conductive trace 112 by at least a distance E of 2 μm. Thus, in the three dimensional patterning, a distance between layers of magnetic film (e.g., the distance D) may be less than a distance between any layer of magnetic film and the conductive trace 112 (e.g., the distance E). Additionally, in some implementations, the number of layers may be increased while the thickness of layers (e.g., the distance C) is decreased. This may enable achieving an even greater Q factor. For example, while three layers of magnetic film are shown by way of example, some implementations may include four, five, or more layers of magnetic film.

In some implementations, the conductive trace 112 may include multiple regions. The one or more layers of magnetic film 114, including the trenches 120, may surround each of the regions. For example, referring again to FIG. 1, the conductive trace 112 may include terminal 116, followed by a first region 141a, followed by a turn, followed by a second region 141b, followed by another turn, followed by a third region 141c, followed by terminal 118 (e.g., forming an open loop of the inductor 110). The first region 141a, the second region 141b, and the third region 141c may each include magnetic film, including the trenches 120, surrounding the region.

FIGS. 6A-6D are examples of inductors including one or more conductive traces and one or more multi-layer stacks in accordance with embodiments. For example, the one or more multi-layer stacks of any of FIGS. 6A-6D could implement the one or more layers of magnetic film 114 with trenches shown in FIGS. 1-5. Referring first to FIG. 6A, an example of a side view of an inductor 110a is shown in accordance with an embodiment. For example, the inductor 110a could be a single turn inductor. The inductor 110a may include one or more multi-layer stacks, each comprising one or more layers of magnetic film (e.g., magnetic film layers 114a, 114b, and 114c) separated by layers of dielectric (e.g., dielectric layers 115a, 115b, 115c, and 115d). For example, the one or more multi-layer stacks may be coupled to the conductive trace 112a via a plated lamination process.

The one or more multi-layer stacks may surround a top, bottom, and sides of the conductive trace 112a. For example, the one or more multi-layer stacks may include a first multi-layer stack 183 under a bottom of the conductive trace 112a. The first multi-layer stack 183 may include multiple layers of magnetic film (e.g., three layers shown in the example) alternating with layers of dielectric. The first multi-layer stack 183 may also include etches implementing the trenches 120 (e.g., trenches 120c and 120d). The etches may be formed, for example, via a step of laser etching, dry reactive etching, or plasma etching, and filling with dielectric, such as polyimide or air, to produce a pattern that results in a higher Q factor for the inductor 110a. The one or more multi-layer stacks may also include a second multi-layer stack 185 that wraps around the top and opposing sides of the conductive trace 112a. The second multi-layer stack 185 may also include multiple layers of magnetic film (e.g., three layers shown in the example) alternating with layers of dielectric (e.g., like the first multi-layer stack 183). The second multi-layer stack 185 may also include etches implementing the trenches 120 (e.g., trenches 120a and 120b). For example, the trenches 120a and 120b may be aligned (e.g., in the Z direction) with trenches 120c and 120d, respectively. The etches may be formed, for example, via another step of laser etching, dry reactive etching, or plasma etching, and filling with dielectric, such as polyimide or air, to produce the pattern resulting in the higher Q factor.

Referring to FIG. 6B, an example of a side view of an inductor 110b is shown in accordance with an embodiment. For example, the inductor 110b could be a multi-turn inductor. The inductor 110b may include one or more multi-layer stacks, each comprising one or more layers of magnetic film (e.g., magnetic film layers 114a, 114b, and 114c) separated by layers of dielectric (e.g., dielectric layers 115a, 115b, 115c, and 115d). The one or more multi-layer stacks may be coupled to multiple conductive traces of the inductor 110b (e.g., different turns of the inductor 110b), such as a group of conductive traces 112a-112c, via a plated lamination process. The one or more multi-layer stacks may surround a top, bottom, and sides of the group of conductive traces 112a-112c. For example, the first multi-layer stack 183 may be under a bottom of the group, and the second multi-layer stack 185 may wrap around the top and opposing sides of the group. The first multi-layer stack 183 may also include etches implementing the trenches above the group (e.g., trenches 120a-120c, above the conductive traces 112a-112c, respectively). The second multi-layer stack 185 may also include etches implementing the trenches below the group (e.g., trenches 120d-120f, below the conductive traces 112a-112c, respectively). The etches may be formed, for example, via laser etching, dry reactive etching, or plasma etching, and filling with dielectric, such as polyimide or air, to produce a pattern that results in a higher Q factor for the inductor 110b.

Referring to FIG. 6C, an example of a side view of an inductor 110c is shown in accordance with an embodiment. For example, the inductor 110c could be another multi-turn inductor. The inductor 110c may include one or more multi-layer stacks, each comprising one or more layers of magnetic film (e.g., magnetic film layers 114a, 114b, and 114c) separated by layers of dielectric (e.g., dielectric layers 115a, 115b, 115c, and 115d). The one or more multi-layer stacks may be coupled to multiple conductive traces in multiple metal layers (e.g., different turns of the inductor 110c), such as a group of conductive traces 112a-112f, via a plated lamination process. For example, conductive traces 112a-112c may be in an upper metal layer above conductive traces 112d-112f in a lower metal layer. The one or more multi-layer stacks may surround a top, bottom, and sides of the group of conductive traces 112a-112f. For example, the first multi-layer stack 183 may be under a bottom of the group, and the second multi-layer stack 185 may wrap around the top and opposing sides of the group. The first multi-layer stack 183 may also include etches implementing the trenches above the group (e.g., trenches 120a-120c, above the conductive traces 112a-112c in the upper metal layer, respectively). The second multi-layer stack 185 may also include etches implementing the trenches below the group (e.g., trenches 120d-120f, below the conductive traces 112a-112c in the lower metal layer, respectively). The etches may be formed, for example, via laser etching, dry reactive etching, or plasma etching, and filling with dielectric, such as polyimide or air, to produce a pattern that results in a higher Q factor for the inductor 110c.

Referring to FIG. 6D, an example of a side view of an inductor 110d is shown in accordance with an embodiment. For example, the inductor 110d could be another single turn inductor. The inductor 110d may include one or more multi-layer stacks, each comprising one or more layers of magnetic film (e.g., magnetic film layers 114a, 114b, and 114c) separated by layers of dielectric (e.g., dielectric layers 115a, 115b, 115c, and 115d). The one or more multi-layer stacks may be coupled to a conductive trace 112a at one or more angles, for example, via a deposition lamination process. The one or more multi-layer stacks may surround a top, bottom, and sides of the conductive trace 112a at the one or more angles. For example, the first multi-layer stack 183 may be under a bottom of the conductive trace 112a, wrapped upward at angles (e.g., a slope of 45 degrees for an upper portion of the sidewalls), along sides of the conductive trace 112a. Thus, each sidewall may be at an angle relative to the top and/or the bottom. The second multi-layer stack 185 may be over a top of the conductive trace 112a and wrapped downward at angles (e.g., a slope of 45 degrees for a lower per portion of the sidewalls), along the sides of the conductive trace 112a. The first multi-layer stack 183 may also include etches implementing the trenches above the conductive trace 112a, and the second multi-layer stack 185 may include etches implementing the trenches below the conductive trace 112a. The etches may be formed, for example, via laser etching, dry reactive etching, or plasma etching, and filling with dielectric, such as polyimide or air, to produce a pattern that results in a higher Q factor for the inductor 110d.

Referring to FIG. 6E, an example of a side view of an inductor 110e is shown in accordance with an embodiment. For example, the inductor 110e could be a multi-turn inductor. The inductor 110e may include one or more multi-layer stacks, each comprising one or more layers of magnetic film (e.g., magnetic film layers 114a, 114b, and 114c) separated by layers of dielectric (e.g., dielectric layers 115a, 115b, 115c, and 115d). The one or more multi-layer stacks may be coupled to multiple conductive traces of the inductor 110e (e.g., different turns of the inductor 110e), such as a group of conductive traces 112a-112c. The one or more multi-layer stacks may be coupled to the group at one or more angles, for example, via a deposition lamination process. The one or more multi-layer stacks may surround a top, bottom, and sides of the group at the one or more angles. For example, the first multi-layer stack 183 may be under a bottom of the group, and the second multi-layer stack 185 may wrap around the top and opposing sides of the group at angles (e.g., a slope of 30 degrees for the sidewalls). Thus, each sidewall may be at an angle relative to the top and/or the bottom. The first multi-layer stack 183 may also include etches implementing the trenches above the group (e.g., trenches 120a-120c, above the conductive traces 112a-112c, respectively). The second multi-layer stack 185 may also include etches implementing the trenches below the group (e.g., trenches 120d-120f, below the conductive traces 112a-112c, respectively). The etches may be formed, for example, via laser etching, dry reactive etching, or plasma etching, and filling with dielectric, such as polyimide or air, to produce a pattern that results in a higher Q factor for the inductor 110e.

Referring to FIG. 6F, an example of a side view of an inductor 110f is shown in accordance with an embodiment. For example, the inductor 110f could be a multi-turn inductor. The inductor 110f may include one or more multi-layer stacks, each comprising one or more layers of magnetic film (e.g., magnetic film layers 114a, 114b, and 114c) separated by layers of dielectric (e.g., dielectric layers 115a, 115b, 115c, and 115d). The one or more multi-layer stacks may be coupled to multiple conductive traces in multiple metal layers (e.g., different turns of the inductor 110f), such as a group of conductive traces 112a-112f. The one or more multi-layer stacks may be coupled to the group at one or more angles, for example, via a deposition lamination process. The one or more multi-layer stacks may surround a top, bottom, and sides of the group at the one or more angles. For example, the first multi-layer stack 183 may be under a bottom of the group, and the second multi-layer stack 185 may wrap around the top and opposing sides of the group at angles (e.g., a slope of 30 degrees for the sidewalls). The first multi-layer stack 183 may also include etches implementing the trenches above the group (e.g., trenches 120a-120c, above the conductive traces 112a-112c, respectively). The second multi-layer stack 185 may also include etches implementing the trenches below the group (e.g., trenches 120d-120f, below the conductive traces 112d-112f, respectively). The etches may be formed, for example, via laser etching, dry reactive etching, or plasma etching, and filling with dielectric, such as polyimide or air, to produce a pattern that results in a higher Q factor for the inductor 110e.

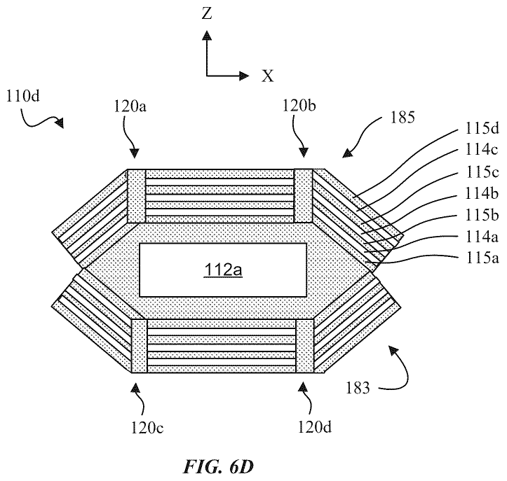

FIGS. 7A-7E are examples of top view patterns (shown above) and side view patterns (shown in the middle) of conductive traces of inductors including magnetic films with trenches (shown below) in accordance with embodiments. For example, FIGS. 7A-7E exemplify inductors 150, 152, 154, 156, and 158, respectively. Each of the examples may include one or more of the multi-layer stacks as shown in FIGS. 6A-6D. Additionally, FIG. 7F is an example of a top view pattern (shown above) and a side view pattern (shown in the middle) of conductive trace of a reference inductor 148 without magnetic film (shown below). The inductors 148-158 may be designed and optimized to achieve an inductance at a target frequency, such as 7 GHz. The inductors 148-158 may have different lengths, widths, inductances, Q factors, and resistances.

The inductor 150 (FIG. 7A), adding three layers of magnetic film and trenches in the Y direction (as compared to the inductor 148), may have a shorter length, a shorter width, about the same inductance, a lower Q factor, and a higher resistance than the inductor 148. The inductor 152 (FIG. 7B), further adding a trench in the X direction above the conductive trace, may have a shorter length, a shorter width, about the same inductance, a lower Q factor, and a lower resistance than the inductor 148. The inductor 154 (FIG. 7C), further adding a trench in the X direction below the conductive trace, may have a shorter length, a shorter width, about the same inductance, a higher Q factor, and a lower resistance than the inductor 148. The inductor 156 (FIG. 7D), adding yet another trench in the X direction (e.g., two trenches), above and below the conductive trace, may have a shorter length, a shorter width, about the same inductance, a higher Q factor, and a lower resistance than the inductor 148. Finally, the inductor 158 (FIG. 7E), adding more trenches in the X direction (e.g., four trenches), above and below the conductive trace, may have a longer length, a shorter width, about the same inductance, a higher Q factor, and a lower resistance than the inductor 148. Thus, the inductor inductors 150, 152, 154, 156, and 158 represent improvements over the inductor 148 in various ways, including smaller form factors (e.g., length and width) and/or higher Q factors.

Additionally, in some implementations, the number of layers may be increased while the thickness of each layer (e.g., the distance C) decreases to achieve a greater Q factor. For example, the inductors 150, 152, 154, 156, and 158 could be designed with four layers or five layers of magnetic film (e.g., instead of three layers as shown) while decreasing the thickness of each layer of magnetic film.

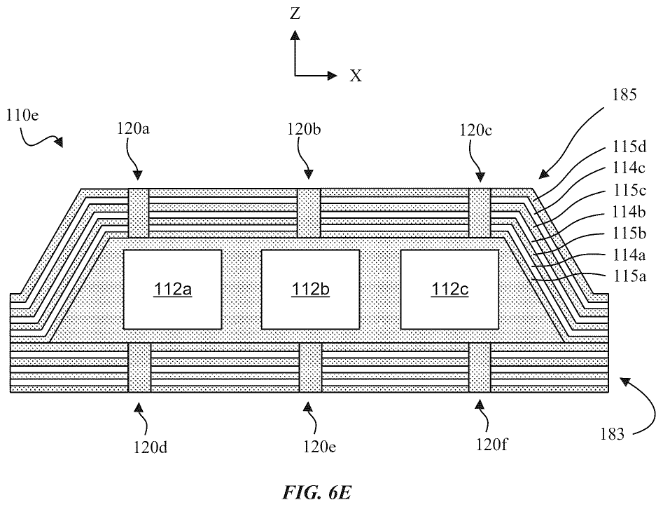

FIG. 8 is an example of the inductor 110 formed in a back-end-of-the-line (BEOL) build-up structure 162 in accordance with an embodiment. For example, the inductor 110 could be an on chip inductor utilized by circuitry of an IC 160 or die. The build-up structure 162 may include the conductive trace 112 and one or more layers of magnetic film (e.g., the one or more multi-layer stacks in FIGS. 6A-6D). A bottom side of the build-up structure 162 may be formed on a top side of a semiconductor substrate 164. The semiconductor substrate 164 may include a plurality of semiconductor devices 166. The build-up structure and the semiconductor substrate 164 together may form the IC 160 or die. A plurality of landing pads 168 may be exposed on a top side of the build-up structure 162 to enable attaching the IC 160 or die in a system (e.g., to IC level packaging).

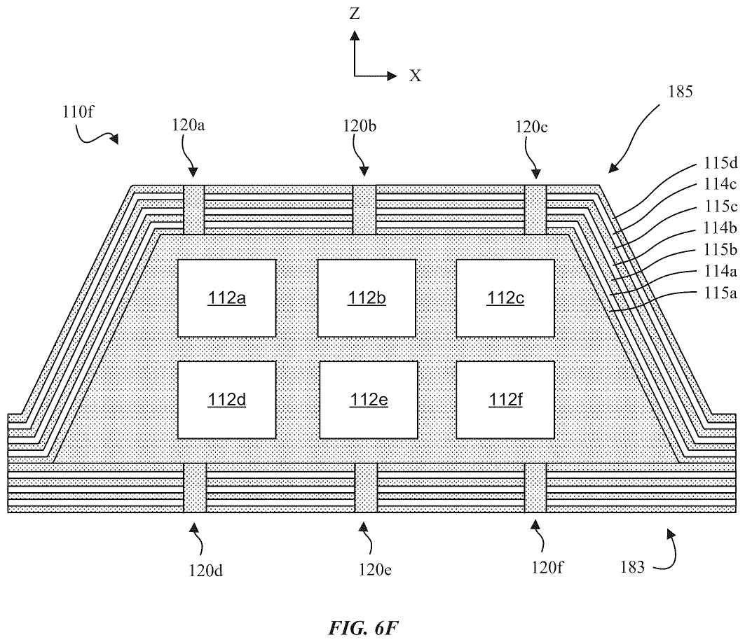

FIG. 9 is an example of the inductor 110 formed in a die level redistribution layer (RDL) 171 in accordance with an embodiment. For example, the inductor 110 could be an on chip inductor utilized by circuitry of an IC 170 or die. The die level RDL 171 may include the conductive trace 112 and one or more layers of magnetic film (e.g., the one or more multi-layer stacks in FIGS. 6A-6D). A plurality of landing pads 172 may be exposed on a top side of the die level RDL 171. The plurality of landing pads 172 may enable attaching the IC 170 or die in a system (e.g., to IC level packaging). A plurality of test pads 174 (e.g., aluminum) may be exposed on a bottom side of the die level RDL 171. The bottom side of the die level RDL 171 may be formed on a top side of a BEOL build-up structure 176 with a passivation layer 178 (e.g., SiNix) formed in between the die level RDL 171 and the build-up structure 176. The build-up structure 176 may include a metal seal ring 180 that prevents encroachment of moisture and impurities into layers of the build-up structure 176. A bottom side of the build-up structure 176 may be formed on a top side of a semiconductor substrate 184. The semiconductor substrate 184 may include a plurality of semiconductor devices 186. The die level RDL 171, the build-up structure 176, and the semiconductor substrate 184 together may form the IC 170 or die.

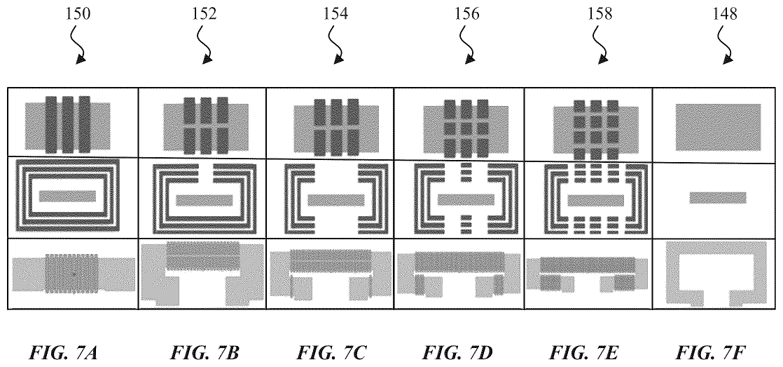

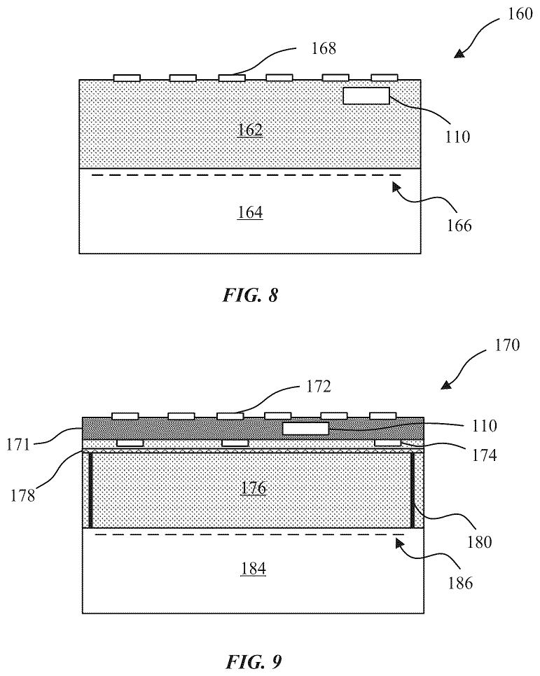

In some implementations, the die level RDL 171, including the inductor 110, may be manufactured via a thin film fabrication. For example, based on utilization of the passivation layer 178 and metal seal ring 180, the die level RDL 171 may be formed via lamination, spin coating, spray coating, or other cost effective techniques, without adversely affecting the build-up structure 176. For example, with additional reference to FIG. 10, the die level RDL 171 may comprise different types and/or thicknesses of dielectric layers 202 and 204, with metallization lines 206 forming line vias 208 thereon. In contrast, the build-up structure 176 can continue to utilize more precise techniques in its formation, such as chemical vapor deposition (CVD). With additional reference to FIG. 11, the build-up structure 176 may be manufactured via a dual damascene fabrication. For example, with additional reference to FIG. 11, the build-up structure 176 may comprise dielectric layers 212 of a same type and/or a same thickness, with metallization lines 214 forming vias 216 (e.g., metal filled openings) thereon.

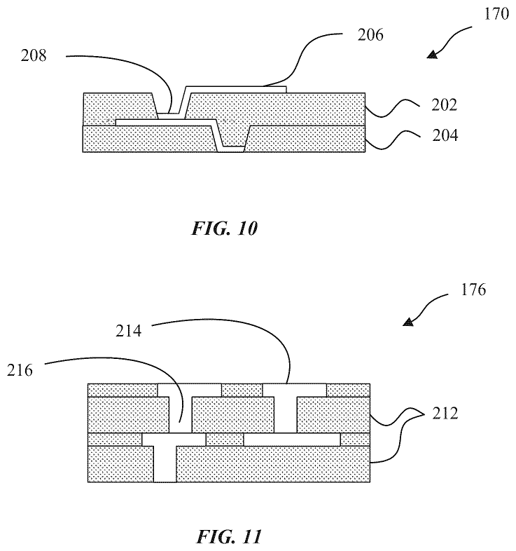

FIG. 12 is an example of the inductor 110 formed in package level RDL 232 in accordance with an embodiment. For example, the inductor 110 could be a package level inductor formed in a package 230. The package level RDL 232 may include the conductive trace 112 and one or more layers of magnetic film (e.g., the one or more multi-layer stacks in FIGS. 6A-6D). The package 230 may include an IC 234 or die comprising a build-up structure and a semiconductor substrate (e.g., the build-up structure 162 and the semiconductor substrate 164, shown by way of example). The IC 234 or die may be encapsulated in a molding compound 235 (e.g., epoxy). The package 230 may also include the package level RDL 232 coupled to the IC 234 or die (e.g., attached to a surface of the die). For example, the IC 234 or die could be a flip chip, and the package level RDL 232 may fan out connections associated with the IC 234 or die. A plurality of landing pads 236 may be exposed on a bottom surface of the package level RDL 232. Additionally, a plurality of bumps 238 may be attached to the plurality of landing pads 236 for attaching the package 230 in a system.

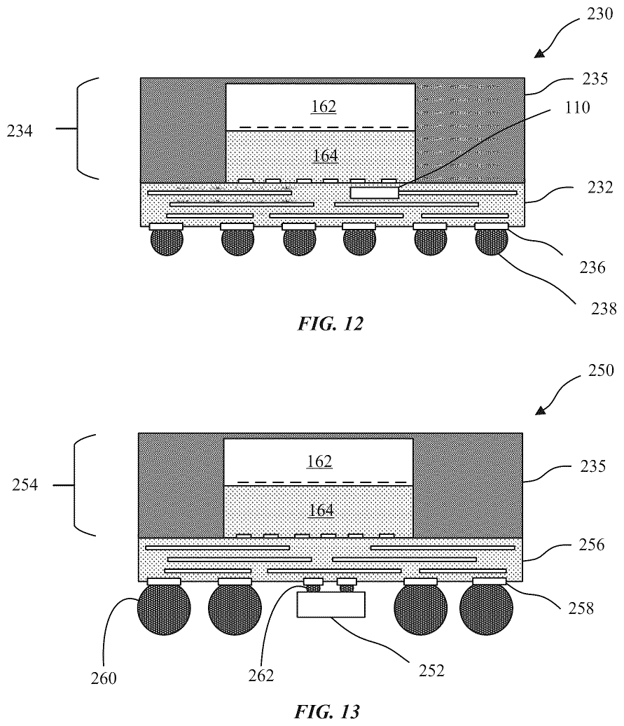

FIG. 13 is an example of the inductor 110 comprised of a discrete integrated passive device (IPD) 252 in accordance with an embodiment. For example, the IPD 252 could comprise a chiplet coupled to a package 250. The IPD 252 may include the conductive trace 112 and one or more layers of magnetic film (e.g., the one or more multi-layer stacks in FIGS. 6A-6D). The package 250 may include an IC 254 or die comprising a build-up structure and a semiconductor substrate (e.g., the build-up structure 162 and the semiconductor substrate 164, shown by way of example). The IC 254 or die may be encapsulated in a molding compound 235 (e.g., epoxy). The package 250 may also include a package level RDL 256 coupled to the IC 254 or die attached to a surface of the IC 254 or die. For example, the IC 254 or die could be a flip chip, and the package level RDL 256 may fan out connections of the IC 254 or die. A plurality of landing pads 258 may be exposed on a bottom surface of the package level RDL 256. Additionally, a plurality of bumps 260 may be attached to the plurality of landing pads 258 for coupling the IPD 252 to the package 250 and/or for attaching the package 250 in a system. In some implementations, a plurality of micro-bumps 262 (e.g., smaller than the plurality of bumps 260) may be attached to some of the plurality of landing pads 258 for coupling the IPD 252 to the package 250.

In utilizing the various aspects of the embodiments, it would become apparent to one skilled in the art that combinations or variations of the above embodiments are possible for inductors including conductive traces and magnetic films with trenches for radio frequency integrated circuits. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An inductor for an integrated circuit (IC), comprising:
a conductive trace; and
one or more magnetic films surrounding a top, a bottom, and sides of the conductive trace, the one or more magnetic films including one or more trenches along a first path directly above a length of the conductive trace, and one or more trenches along a second path directly above a width of the conductive trace, to form a plurality of sections.

2. The inductor of claim 1, wherein trenches of the one or more magnetic films pass completely through the one or more magnetic films between sections of the plurality of sections.

3. The inductor of claim 1, wherein the one or more magnetic films includes one or more trenches along a third path directly below the width of the conductive trace, and one or more trenches along a fourth path directly below the length of the conductive trace.

4. The inductor of claim 3, wherein the one or more trenches along the first path are aligned with the one or more trenches along the third path, and wherein the one or more trenches along the second path are aligned with the one or more trenches along the fourth path.

5. The inductor of claim 3, wherein the one or more magnetic films includes one or more trenches along a fifth path directly across a thickness of the conductive trace.

6. The inductor of claim 1, wherein a plurality of magnetic films surround the conductive trace.

7. The inductor of claim 6, wherein the plurality of magnetic films includes at least three layers of magnetic film.

8. The inductor of claim 6, wherein a first distance between layers of the plurality of magnetic films is less than a second distance between the plurality of magnetic films and the conductive trace.

9. The inductor of claim 6, wherein trenches of the plurality of magnetic films pass completely through the plurality of magnetic films between sections of the plurality of sections.

10. The inductor of claim 6, wherein the plurality of magnetic films is under the bottom of the conductive trace, and further comprising:
a second plurality of magnetic films wrapped around a side and the top the conductive trace.

11. The inductor of claim 1, wherein the conductive trace and the one or more magnetic films are formed in a back-end-of-the-line (BEOL) build-up structure over a semiconductor substrate.

12. The inductor of claim 1, wherein the conductive trace and the one or more magnetic films are formed in a die level redistribution layer (RDL).

13. The inductor of claim 1, wherein the conductive trace and the one or more magnetic films are formed in a package level RDL coupled to a die.

14. The inductor of claim 1, wherein the conductive trace and the one or more magnetic films comprise a discrete integrated passive device (IPD) coupled to a discrete die.

15. The inductor of claim 1, further comprising:
a second region of the conductive trace, wherein the one or more magnetic films further includes one or more trenches to form a second plurality of sections surrounding the second region.

16. An inductor for an integrated circuit (IC), comprising:
a conductive trace; and
one or more multi-layer stacks surrounding a top, a bottom, and sides of the conductive trace, the one or more multi-layer stacks including layers of magnetic film separated from one another by layers of dielectric, the one or more multi-layer stacks further including one or more trenches along a path directly above at least one of a length or a width of the conductive trace to form a plurality of sections.

17. The inductor of claim 16, wherein trenches of the one or more multi-layer stacks pass completely through the one or more multi-layer stacks between sections of the plurality of sections.

18. The inductor of claim 16, wherein the one or more multi-layer stacks includes one or more trenches along a path directly below at least one of the length or the width of the conductive trace.

19. The inductor of claim 18, wherein the one or more trenches along the path directly above the conductive trace are aligned with the one or more trenches along the path directly below the conductive trace.

20. The inductor of claim 18, wherein the one or more multi-layer stacks includes one or more trenches along a fifth path directly across a thickness of the conductive trace.
